(19) United States
(12) Patent Application Publication
(10) Pub. No.: US 2026/0343881 A1
(43) Pub. Date: Oct. 29, 2026

(54) MEMORY DEVICE AND MANUFACTURING METHOD THEREOF

(71) Applicant: MACRONIX International Co., Ltd., Hsinchu (TW)

(72) Inventor: Chih-Kai Yang, Kaohsiung City (TW)

(73) Assignee: MACRONIX International Co., Ltd., Hsinchu (TW)

(21) Appl. No.: 19/193,895

(22) Filed: Apr. 29, 2025

(51) Int. Cl. H10B 43/27; H10B 43/10

(52) U.S. Cl. CPC H10B 43/27; H10B 43/10

(57) ABSTRACT

A memory device, applicable to a 3D NAND flash memory and having a high capacity and/or a high performance. The memory device includes a substrate, a source line plane, a stack structure, a plurality of slits, and a plurality of vertical channels. The source line plane is disposed over the substrate. The stack structure includes a plurality of insulating layers and a plurality of conductive layers alternately stacked over the source line plane. The slits penetrate the stack structure and divide the stack structure into a plurality of zones, wherein each of the slits includes a first portion close to the source line plane and a second portion located on the first portion. A top of the first portion of the slit is larger than a bottom of the second portion thereof. The vertical channels penetrate the stack structure in the zones and the source line plane.

### BACKGROUND

### Technical Field

The disclosure relates to a memory device and a manufacturing method thereof.

### Description of Related Art

Since a non-volatile memory element has an advantage that data stored therein does not disappear after power is turned off, the non-volatile memory element has become a widely used memory element in personal computers and other electronic devices.

In order to further improve integration of the memory device, a three-dimensional (3D) memory device has been developed, such as a NAND flash memory, a NOR flash memory, a ROM flash memory, etc. However, as storage layers increase in the 3D memory device, there are challenges related to process and structure.

### SUMMARY

The disclosure provides a memory device and a manufacturing method thereof, which provide suitable slit structure as the storage layer thickens.

In an embodiment of the disclosure, a memory device includes a substrate, a source line plane, a stack structure, a plurality of slits, and a plurality of vertical channels. The source line plane is disposed over the substrate. The stack structure includes a plurality of insulating layers and a plurality of conductive layers that are alternately stacked over the source line plane. The slits penetrate the stack structure and divide the stack structure into a plurality of zones. Each of the slits includes a first portion close to the source line plane and a second portion located on the first portion. A top of the first portion of the slit is larger than a bottom of the second portion. The vertical channels penetrate the stack structure in the zones and the source line plane.

In another embodiment of the disclosure, a manufacturing method of a memory device includes the following steps. A lower semiconductor layer is formed over a substrate. A dielectric stack is formed on the lower semiconductor layer. An upper semiconductor layer is formed on the dielectric stack. A first stack structure is formed on the upper semiconductor layer. The first stack structure includes a plurality of insulating layers and a plurality of sacrificial layers that are alternately stacked. A first trench is formed in the first stack structure until the upper semiconductor layer is exposed. An exposed surface of the upper semiconductor layer is oxidized to form an oxidized film. The first trench is filled with a sacrificial material. A second stack structure is formed on the first stack structure and the sacrificial material in the first trench. A plurality of vertical channels are formed to penetrate the second stack structure, the first stack structure, the upper semiconductor layer, the dielectric stack, and the lower semiconductor layer. A second trench is formed in the second stack structure on the first trench until the sacrificial material is exposed. A width of a top of the first trench is larger than a width of a bottom of the second trench. The sacrificial material is removed.

Based on the above, in the manufacturing method of the memory device according to the embodiments of the disclosure, the stack structure and the slit are formed in several stages. A larger trench is first formed at a bottom of the stack structure followed by filling with the sacrificial material. A deeper trench is then formed on the trench after reminding stack structure was formed, and the sacrificial material is used as an etching stop layer. Therefore, a function and an appearance of a subsequently formed slits may meet the requirements.

### BRIEF DESCRIPTION OF THE DRAWINGS

FIG. 1 is a plane view of a memory device according to an embodiment of the disclosure.

FIG. 2 is a cross-sectional view of the memory device along line II-II′ in FIG. 1.

FIGS. 3A to 3R are cross-sectional views of a manufacturing process of a memory device according to another embodiment of the disclosure.

### DESCRIPTION OF THE EMBODIMENTS

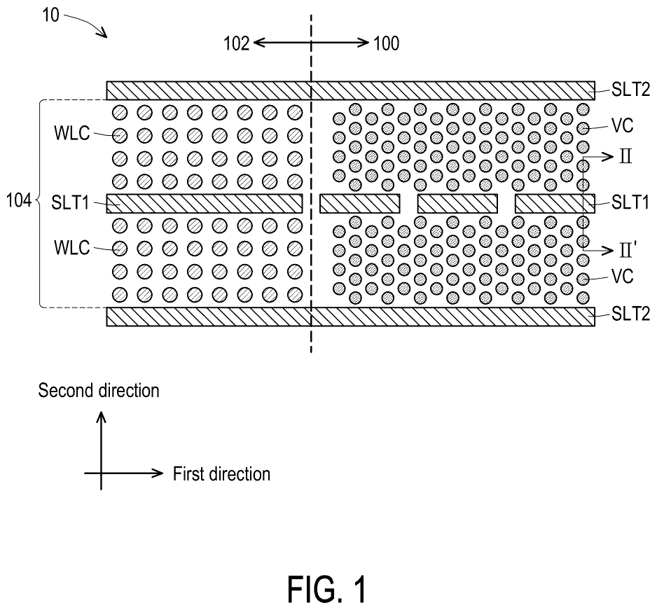

FIG. 1 is a plane view showing a memory device according to an embodiment of the disclosure.

In FIG. 1, a memory device 10 is a 3D memory device, and the memory device 10 may include a memory region 100 and a word line staircase region 102. The memory region 100 has a plurality of vertical channels VC passing through a stack structure (not shown), and the word line staircase region 102 has a plurality of word line contacts WLC coupled to word lines in the stack structure in the memory region 100. The memory device 10 further has slits SLT2 that divide the stack structure into zones 104. Although only one zone 104 is shown in FIG. 1, it is understood that the memory device 10 may include a plurality of zones 104. In some embodiments, in addition to the slits SLT2 that are continuous lines extending along a first direction, the memory device 10 further has slit SLT1 disposed between the slits SLT2. The slit SLT1 include a plurality of sub slits extending along the first direction. For example, the slit SLT1 in FIG. 1 has four sub slits, but the disclosure is not limited thereto.

A detailed structure of the slit SLT1 will be described below.

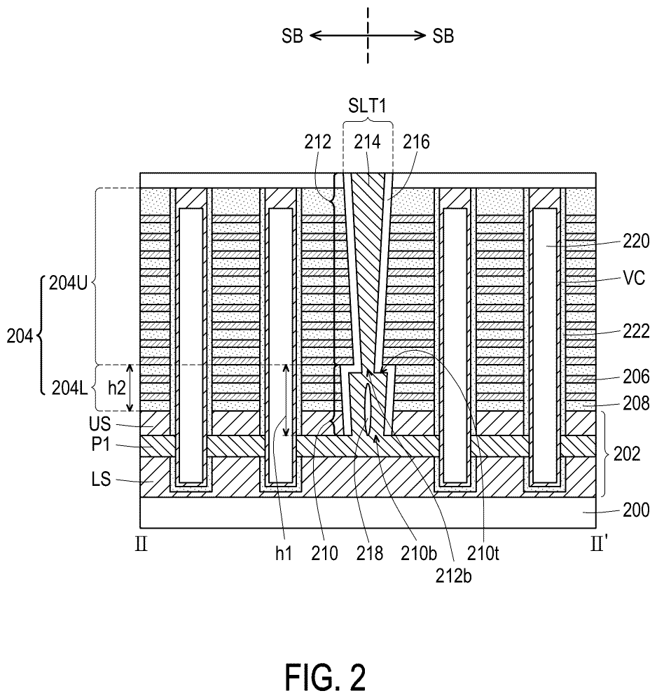

FIG. 2 is a cross-sectional view of the memory device along line II-II′ of FIG. 1, wherein the line II-II′ is parallel to a second direction of FIG. 1. Referring to FIG. 2, the memory device at least includes a substrate 200, a source line plane 202, a stack structure 204, a slit SLT1, and a plurality of vertical channels VC. In the embodiment of the disclosure, the structure of the slits SLT2 in FIG. 1 is the same as that of the slit SLT1, and thus the slits SLT2 and the slit SLT1 may be made together through a same process.

In FIG. 2, a source line plane 202 is disposed over a substrate 200, wherein the source line plane 202 may include a lower semiconductor layer LS, an upper semiconductor layer US, and a conductive material P1 between the lower semiconductor layer LS and the upper semiconductor layer US. In some embodiments, the lower semiconductor layer LS, the upper semiconductor layer US, and the conductive material P1 may include doped or undoped semiconductor materials, such as doped or undoped polysilicon. A stack structure 204 includes a plurality of conductive layers 206 and a plurality of insulating layers 208 that are alternately stacked over the source line plane 202. In some embodiments, the conductive layers 206 may include a conductive material, such as tungsten (W), and the insulating layers 208 may include an oxide, such as silicon oxide. The slit SLT1 penetrates the entire stack structure 204 and divides the stack structure 204 into a plurality of sub-zones SB, wherein the slit SLT1 includes a first portion 210 close to the source line plane 202 and a second portion 212 located on the first portion 210. In some embodiments, the stack structure 204 includes a lower portion 204L close to the source line plane 202 and an upper portion 204U located over the lower portion 204L, and an interface between the upper portion 204U and the lower portion 204L is at a same level as an interface between the second portion 212 and the first portion 210 of the slit SLT1, wherein a number of layers of the lower portion 204L is less than a number of layers of the upper portion 204U. In the slit SLT1, a top 210t of the first portion 210 is larger than a bottom 212b of the second portion 212. In some embodiments, a ratio of a height h2 of the lower portion 204L of the stack structure 204 to a height h1 of the first portion 210 of the slit SLT1 is 2:3 to 5:6. In some embodiments, a section shape of the first portion 210 is an inverted trapezoid. In some embodiments, a bottom 210b of the first portion 210 is larger than a bottom 212b of the second portion 212.

In some embodiments, the slit SLT1 includes a conductive trench contact 214 and an insulation spacer 216 disposed at sidewalls of the conductive trench contact 214. In some embodiments, the conductive trench contact 214 may include a conductive material, such as polysilicon or tungsten. In some embodiments, the insulation spacer 216 may include an oxide, such as low temperature oxide (LTO). Due to a depth of the slit SLT1, a seam 218 may be present in the conductive trench contact 214 in the first portion 210. The conductive trench contact 214 is electrically connected to the source line plane 202, and the conductive trench contact 214 and a conductive material P1 of the source line plane 202 may be the same material, so an interface between the conductive trench contact 214 and the source line plane 202 is not shown in the figure.

In FIG. 2, the vertical channels VC penetrate the stack structure 204 and the source line plane 202. In some embodiments, the vertical channels VC are located on surfaces of insulating pillars 220, which may include doped or undoped semiconductor material, such as doped polysilicon or undoped polysilicon. A material of the insulating pillars 220 may include silicon oxide or other suitable insulating material. In some embodiments, a charge storage structure 222 is further disposed between the vertical channels VC and the stack structure 204, wherein the charge storage structure 222 may include a known multilayer structure, such as an ONO (oxide-nitride-oxide) structure, an ONONO (oxide-nitride-oxide-nitride-oxide) structure, a SONOS (silicon-oxide-nitride-oxide-silicon) structure, a BE-SONOS (bandgap engineered silicon-oxide-nitride-oxide-silicon) structure, a TANOS (tantalum nitride-aluminum oxide-silicon nitride-silicon oxide-silicon) structure, or the like.

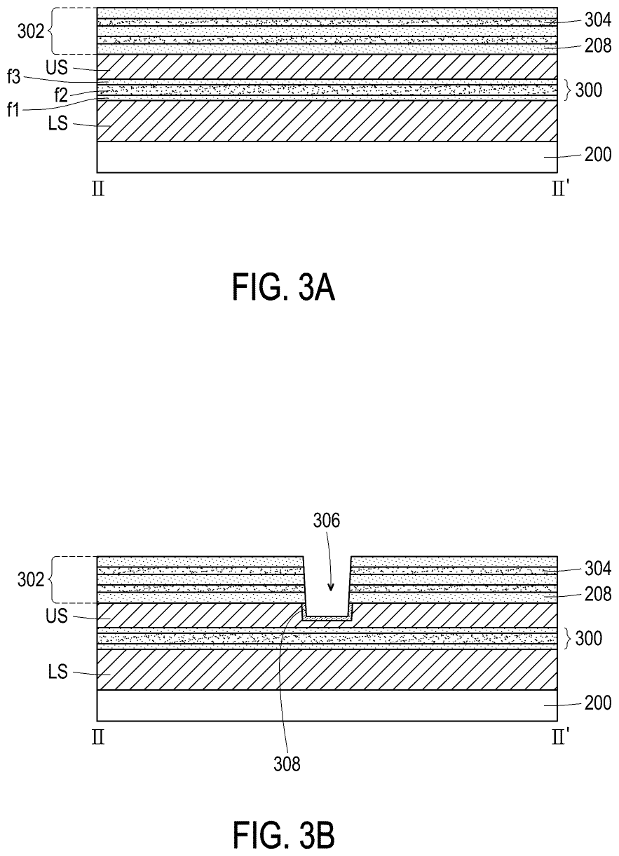

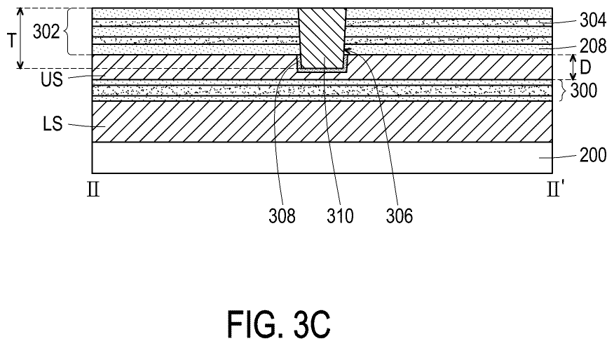

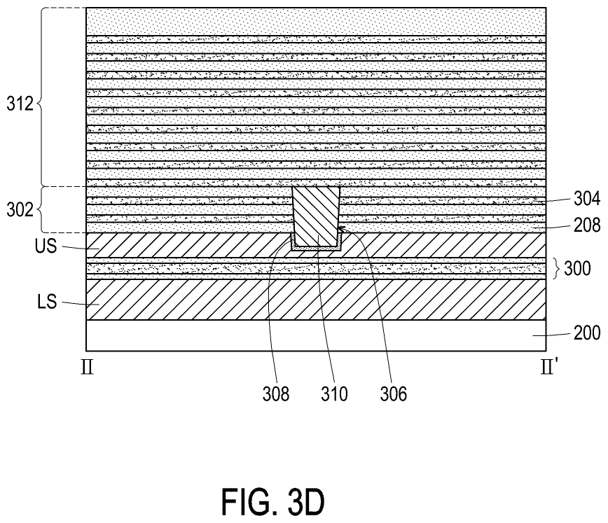

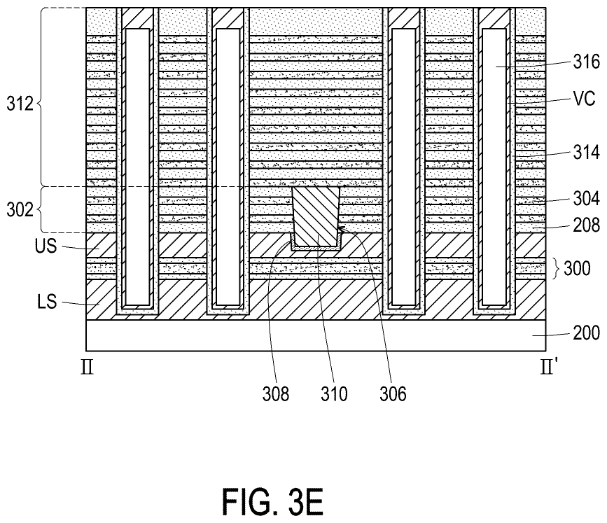

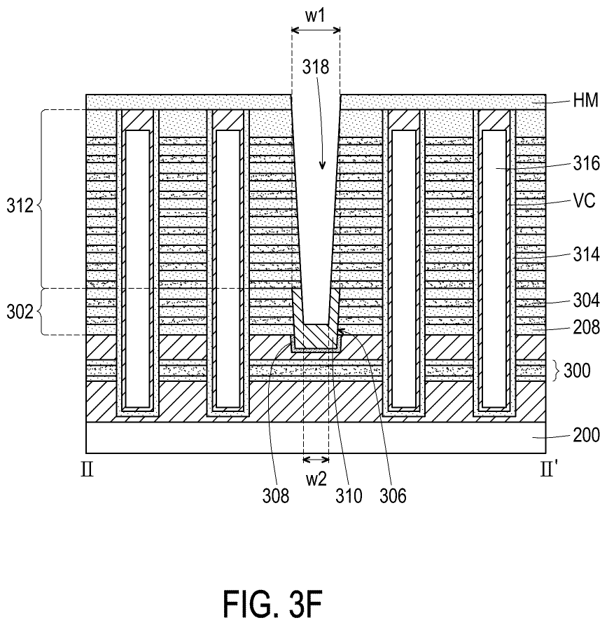

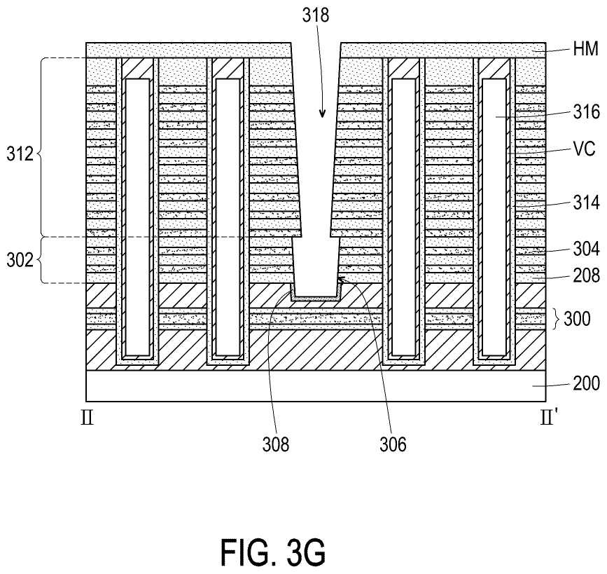

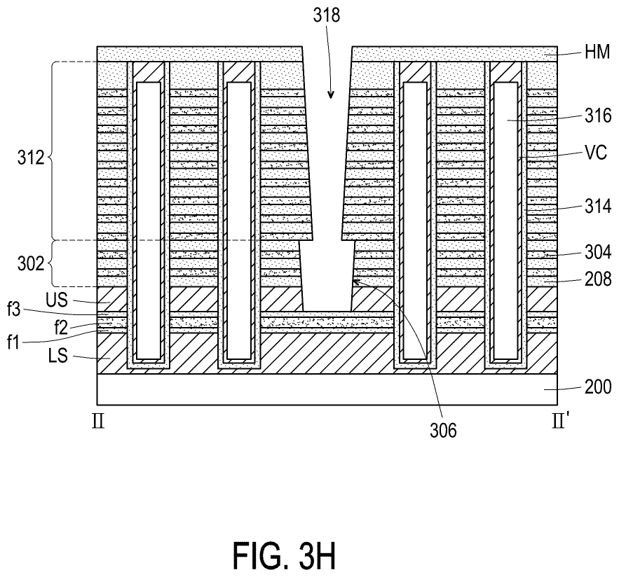

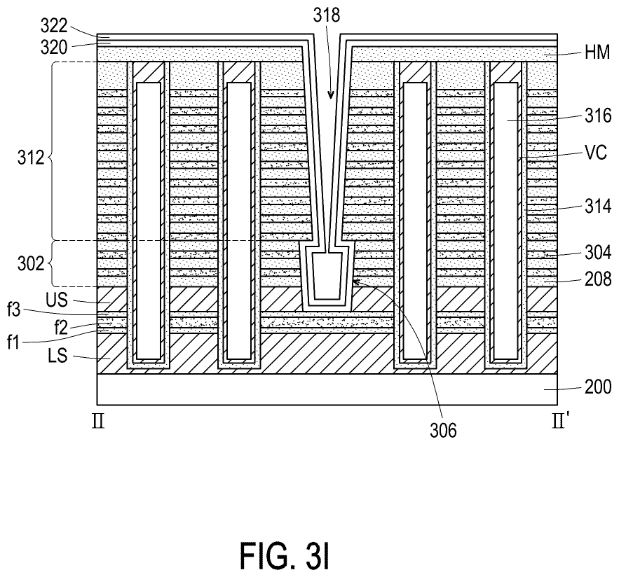

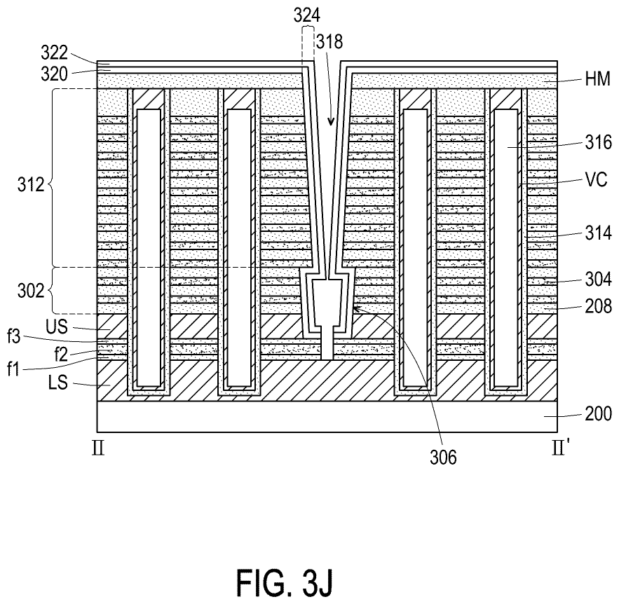

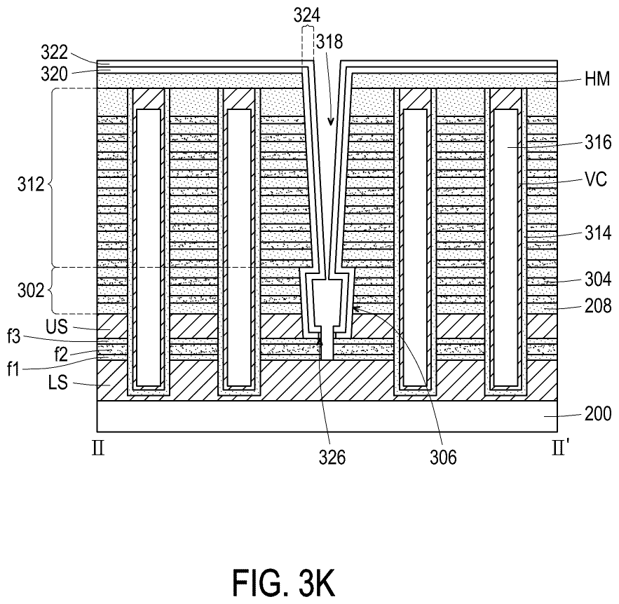

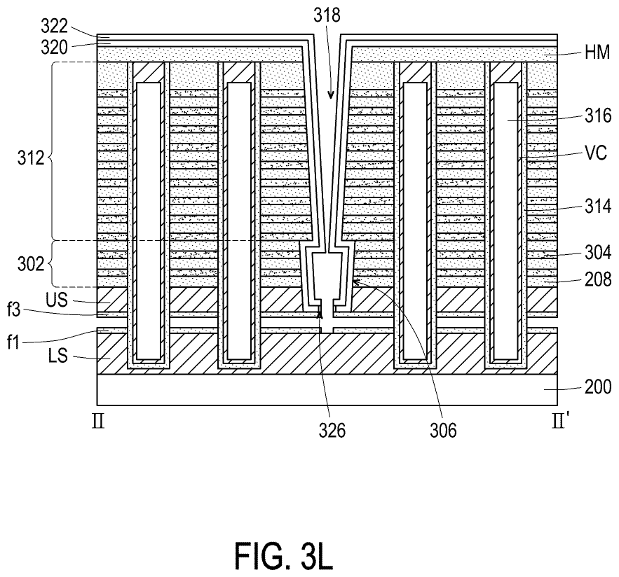

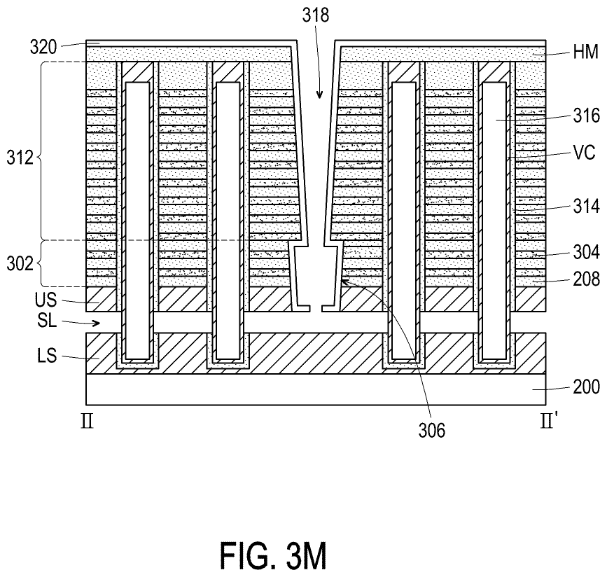

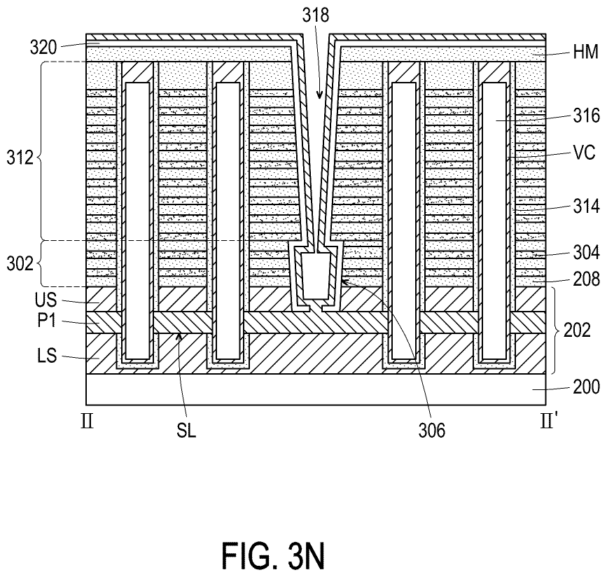

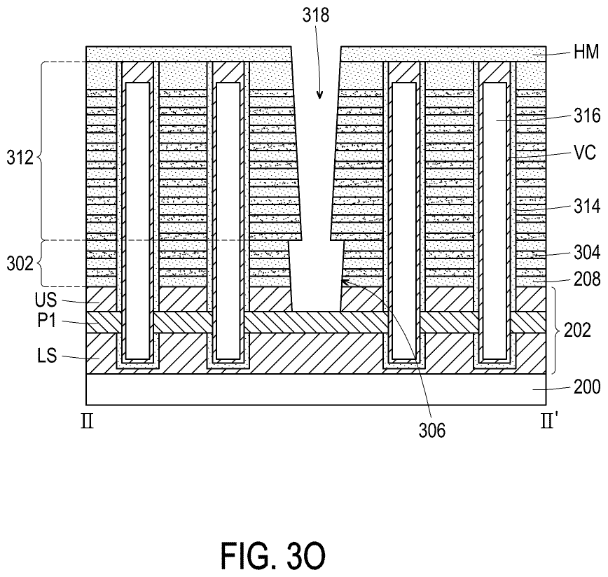

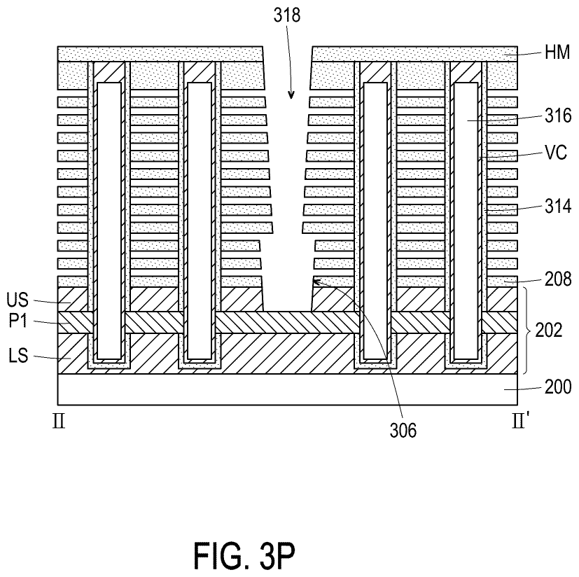

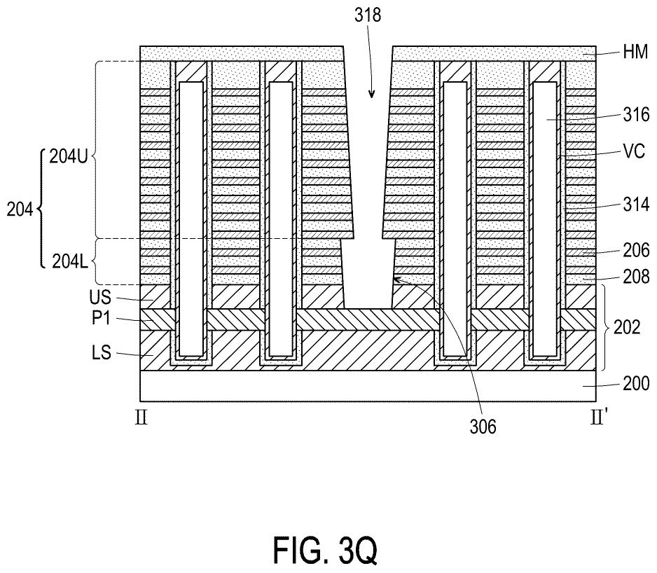

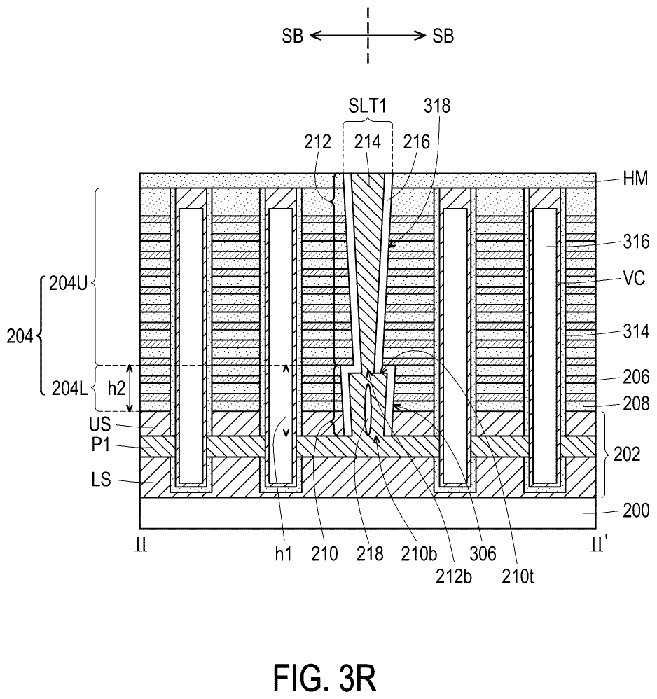

FIGS. 3A to 3R are cross-sectional views of a manufacturing process of a memory device according to another embodiment of the disclosure, wherein same or similar parts and components as those in FIG. 2 are denoted by same element symbols. Reference may be made to the previous embodiment for the related content of the same or similar parts and components, and the related content will not be repeated here.

Referring to FIG. 3A, a lower semiconductor layer LS is formed over a substrate 200. A dielectric stack 300 is formed on the lower semiconductor layer LS, wherein the dielectric stack 300 may be a multilayer structure, such as a dielectric film f1, a dielectric film f2, and a dielectric film f3. To cooperate in subsequent process, a material of a middle dielectric film f2 may be different from materials of the dielectric film f1 and the dielectric film f3. In some embodiments, the dielectric film f2 may include silicon nitride, and the dielectric films f1 and f3 may include silicon oxide. Thereafter, an upper semiconductor layer US is formed on the dielectric stack 300. In some embodiments, the above structural layers may be sequentially deposited by a method such as chemical vapor deposition (CVD). Then, a first stack structure 302 is formed on the upper semiconductor layer US, wherein the first stack structure 302 includes a plurality of insulating layers 208 and a plurality of sacrificial layers 304 that are alternately stacked. In some embodiments, the material of the sacrificial layers 304 has an etching selectivity with respect to the insulating layers 208, such as a nitride.

Referring to FIG. 3B, a first trench 306 is formed in the first stack structure 302 until the upper semiconductor layer US is exposed. A method of forming the first trench 306 may include a photolithographic etching process to remove a part of the first trench 306 and slightly etch a part of the upper semiconductor layer US. The first trench 306 in the figure is recessed into a top of the upper semiconductor layer US, but the disclosure is not limited thereto; in some embodiments, since a height (or thickness) of the first stack structure 302 is not large, the first trench 306 may be easily stopped above the upper semiconductor layer US. That is, a bottom surface of the first trench 306 is coplanar with a top surface of the upper semiconductor layer US. Thereafter, an exposed surface of the upper semiconductor layer US is oxidized to form an oxidized film 308. From a viewpoint of not easily etching through the upper semiconductor layer US, a thickness of the oxidized film 308 may be 10 Å to 300 Å, for example, 20 Å to 300 Å, or 50 Å to 300 Å.

Referring to FIG. 3C, a first trench 306 is filled with a sacrificial material 310. In some embodiments, the sacrificial material 310 may be deposited into the first trench 306, and then chemical mechanical polishing (CMP) may be performed so that a top surface of the sacrificial material 310 may be coplanar with a top surface of the first stack structure 302. In some embodiments, the sacrificial material 310 includes a metal material (such as W, Ti, TiN, etc.), polysilicon, or a carbon material. When the sacrificial material 310 is a metal material, a ratio of a height T of the sacrificial material 310 to a height D of the upper semiconductor layer US may be, for example, 1:1 to 2:1. When the sacrificial material 310 is a polysilicon or carbon material, a ratio of the height T of the sacrificial material 310 to the height D of the upper semiconductor layer US may be 2:1 to 5:1. The aforementioned height ratio is also applicable to a case where the first trench 306 is etched to stop above the upper semiconductor layer US.

Referring to FIG. 3D, a second stack structure 312 is formed on the first stack structure 302 and the sacrificial material 310 in the first trench 306, wherein the second stack structure 312 includes a plurality of insulating layers 208 and a plurality of sacrificial layers 304 that are alternately stacked. In some embodiments, the insulating layers 208 in the second stack structure 312 and the insulating layers 208 in the first stack structure 302 may be the same material. The sacrificial layers 304 in the second stack structure 312 and the sacrificial layers 304 in the first stack structure 302 may be the same material.

Referring to FIG. 3E, vertical channels VC are formed to penetrate the second stack structure 312, the first stack structure 302, the upper semiconductor layer US, the dielectric stack 300, and the lower semiconductor layer LS. Moreover, other steps may be performed before and after forming the vertical channels VC, such as, but not limited to, first forming openings through the above structures, and then forming a charge storage structure 314 in the openings. In some embodiments, the charge storage structure 314 may be conformally formed on sidewalls and a bottom surface of the openings, and a material of the charge storage structure 314 may refer to the charge storage structure 222 in FIG. 2. Then, the vertical channels VC are formed on inner sidewalls and a bottom surface of the charge storage structure 314. Next, an insulating pillar 316 is formed on inner surfaces of the vertical channels VC. A material of the insulating pillar 316 may refer to the insulating pillar 220 in FIG. 2.

Referring to FIG. 3F, a second trench 318 is formed in the second stack structure 312 on the first trench 306 until the sacrificial material 310 is exposed. In some embodiments, a method of forming the second trench 318 includes, for example, first forming a hard mask HM, and then etching the second stack structure 312 using the hard mask HM as an etching mask. The sacrificial material 310 may serve as an etching stop layer during etching of the second stack structure 312. In some embodiments, since the second trench 318 is deeper, sidewalls thereof are not vertical but become narrower toward a bottom (the first trench 306), so that a width w1 of a top of the first trench 306 may be greater than a width w2 of a bottom of the second trench 318.

Referring to FIG. 3G, the sacrificial material 310 in FIG. 3F is removed. When the sacrificial material 310 is polysilicon, since there is an etching selectivity between the sacrificial material 310 and the insulating layers 208 and the sacrificial layers 304, a contour of the first trench 306 and the second trench 318 does not change much. Moreover, the existence of the oxidized film 308 ensures that a structure underneath will not be etched through during removal of the sacrificial material 310.

Referring to FIG. 3H, the oxidized film 308 is first removed to expose a part of the upper semiconductor layer US, wherein the oxidized film 308 and the insulating layers 208 may be of the same material, so a part of the insulating layers 208 may also be removed. However, since the oxidized film 308 is very thin, the contour of the first trench 306 and the second trench 318 is not greatly affected. Thereafter, the upper semiconductor layer US is etched until the dielectric film f3 is exposed. Since the upper semiconductor layer US is polysilicon, the contour of the first trench 306 and the second trench 318 is not greatly affected during the etching.

Subsequent processes are to form a slit having a circuit function, but the disclosure is not limited thereto. In some embodiments, the first trench 306 and the second trench 318 may be directly filled with an insulating material.

Referring to FIG. 3I, a first protective layer 320 and a second protective layer 322 are sequentially deposited to be conformally formed on sidewalls and bottom surfaces of the first trench 306 and the second trench 318. In some embodiments, the first protective layer 320 and the second protective layer 322 are different materials. For example, the first protective layer 320 is a polysilicon layer, and the second protective layer 322 is an oxide layer.

Referring to FIG. 3J, the first protective layer 320 and the second protective layer 322 are subjected to etch-back to form a protective spacer 324 on inner sidewalls of the second trench 318 and the first trench 306. Then, using the protective spacer 324 as an etching mask, the exposed dielectric film f3 and a dielectric film f2 below the dielectric film f3 and a dielectric film f1 are removed, and etching may stop at the lower semiconductor layer LS.

Referring to FIG. 3K, the first protective layer 320 in the protective spacer 324 is oxidized so that a part thereof becomes an oxide 326, to prevent the first protective layer 320 from being damaged during a subsequent process.

Referring to FIG. 3L, the dielectric film f2 in FIG. 3K is removed. When the dielectric film f2 is a silicon nitride layer, since the second protective layer 322, the oxide 326, the dielectric film f3, and the dielectric film f1 are not silicon nitride, other structural layers are not easily affected during etching.

Referring to FIG. 3M, the dielectric film f1 and the dielectric film f3 in FIG. 3L are removed to form a source layer space SL. Since the dielectric film f1 and the dielectric film f3 are silicon oxide, the second protective layer 322 in FIG. 3L is also removed. During removal of the dielectric film f1 and the dielectric film f3, the charge storage structure 314 is also etched such that sidewalls of each vertical channel VC are exposed.

Referring to FIG. 3N, the source layer space SL is filled with a conductive material P1 to form the source line plane 202. The conductive material P1 may cover a surface of the first protective layer 320.

Referring to FIG. 3O, a topmost portion of the conductive material P1 and the conductive material P1 located in the second trench 318 and the first trench 306 are first removed, and then the first protective layer 320 in FIG. 3N is removed. At this time, no other structure is present in the first trench 306 and the second trench 318, and the second stack structure 312 and the first stack structure 302 are exposed.

Referring to FIG. 3P, the sacrificial layers 304 in FIG. 3O are completely removed. This process is also called a replacement metal gate process. For example, an etching step may be performed through the second trench 318 and the first trench 306, and the etching step may include wet etching, such as using hot phosphoric acid or other suitable chemicals.

Referring to FIG. 3Q, a space between the insulating layers 208 is filled with the conductive layers 206 to complete the replacement metal gate process. A method of forming the conductive layers 206 may include filling the space between the insulating layers 208 with a conductive material, and then etching back the conductive material to completely remove the conductive material adjacent to the first trench 306 and the second trench 318. The conductive layers 206 in the figure are metal gates and may serve as word lines in the memory device.

Referring to FIG. 3R, an insulation spacer 216 is formed on sidewalls of the second trench 318 and the first trench 306. Then, the second trench 318 and the first trench 306 are filled with a conductive material, and the conductive material outside the second trench 318 is removed through a planarization process such as CMP, so as to form a conductive trench contact 214. A structure in FIG. 3R is substantially similar to the structure in FIG. 2.

In summary, a memory device according to an embodiment of the disclosure includes slits having a specific structure, which may ensure that functions and shapes of the slits meet requirements. Furthermore, a manufacturing method of the memory device according to an embodiment of the disclosure may be applied to 3D memory devices, such as NAND flash memory, NOR flash memory, ROM flash memory, or the like.

What is claimed is:

1. A memory device, comprising:
a substrate;
a source line plane disposed over the substrate;
a stack structure comprising a plurality of insulating layers and a plurality of conductive layers alternately stacked over the source line plane;
a plurality of slits penetrating the stack structure and dividing the stack structure into a plurality of zones, wherein each of the plurality of slits comprises a first portion close to the source line plane and a second portion located on the first portion; and
a plurality of vertical channels penetrating the stack structure in the plurality of zones and the source line plane, wherein
a top of the first portion is larger than a bottom of the second portion.

2. The memory device of claim 1, wherein the stack structure comprises a lower portion close to the source line plane and an upper portion located on the lower portion, and an interface between the upper portion and the lower portion is at a same level as an interface between the second portion and the first portion of each of the plurality of slits.

3. The memory device of claim 2, wherein a layer number of the lower portion is less than a layer number of the upper portion.

4. The memory device of claim 2, wherein a ratio of a height of the lower portion of the stack structure to a height of the first portion of each of the plurality of slits is 2:3 to 5:6.

5. The memory device of claim 1, wherein each of the plurality of slits comprises a conductive trench contact and an insulation spacer disposed at sidewalls of the conductive trench contact.

6. The memory device of claim 5, wherein there is a seam in the conductive trench contact in the first portion.

7. The memory device of claim 5, wherein the conductive trench contact is electrically connected to the source line plane.

8. The memory device of claim 1, wherein a section shape of the first portion is an inverted trapezoid.

9. The memory device of claim 1, wherein a bottom of the first portion is larger than the bottom of the second portion.

10. The memory device of claim 1, wherein the plurality of slits comprise:
two first slits, wherein each of the two first slits is a continuous line extending along a first direction; and
a second slit disposed between the two first slits, wherein the second slit comprises a plurality of sub slits extending along the first direction.

11. A manufacturing method of a memory device, comprising:
forming a lower semiconductor layer over a substrate;
forming a dielectric stack on the lower semiconductor layer;
forming an upper semiconductor layer on the dielectric stack;
forming a first stack structure on the upper semiconductor layer, wherein the first stack structure comprises a plurality of insulating layers and a plurality of sacrificial layers that are alternately stacked;
forming a first trench in the first stack structure until the upper semiconductor layer is exposed;
oxidizing an exposed surface of the upper semiconductor layer to form an oxidized film;
filling the first trench with a sacrificial material;
forming a second stack structure on the first stack structure and the sacrificial material in the first trench;
forming a plurality of vertical channels penetrating the second stack structure, the first stack structure, the upper semiconductor layer, the dielectric stack, and the lower semiconductor layer;
forming a second trench in the second stack structure on the first trench until the sacrificial material is exposed, wherein a width of a top of the first trench is larger than a width of a bottom of the second trench; and
removing the sacrificial material.

12. The manufacturing method of the memory device of claim 11, wherein the sacrificial material is a metal material, and a ratio of a height of the sacrificial material to a height of the upper semiconductor layer is 1:1 to 2:1.

13. The manufacturing method of the memory device of claim 11, wherein the sacrificial material is polysilicon or a carbon material, and a ratio of a height of the sacrificial material to a height of the upper semiconductor layer is 2:1 to 5:1.

14. The manufacturing method of the memory device of claim 11, wherein the second stack structure comprises a plurality of insulating layers and a plurality of sacrificial layers that are alternately stacked.

15. The manufacturing method of the memory device of claim 11, wherein a thickness of the oxidized film is 10 Å to 300 Å.

16. The manufacturing method of the memory device of claim 11, wherein after removing the sacrificial material, further comprises:
removing the oxidized film to partially expose the upper semiconductor layer;
etching the upper semiconductor layer until the dielectric stack is exposed;
forming a protective spacer on an inner sidewall of the second trench and the first trench;
removing the dielectric stack to form a source layer space; and
filling the source layer space with a conductive material.

17. The manufacturing method of the memory device of claim 16, wherein during removing the dielectric stack, sidewalls of each of the plurality of vertical channels is exposed.

18. The manufacturing method of the memory device of claim 16, wherein after filling the source layer space with the conductive material, further comprises:
removing the protective spacer; and
replacing the plurality of sacrificial layers with a metal gate in a replacement metal gate process.

19. The manufacturing method of the memory device of claim 18, wherein after the replacement metal gate process, further comprises:
forming an insulation spacer on sidewalls of the second trench and the first trench; and
forming a conductive trench contact in the second trench and the first trench.

20. The manufacturing method of the memory device of claim 19, wherein a material of the conductive trench contact comprises a same material as the conductive material.
